(19) United States
(12) Patent Application Publication
(10) Pub. No.: US 2018/0304827 A1
(43) Pub. Date: Oct. 25, 2018

(54) CURRENT CONTROL DEVICE, CURRENT CONTROL METHOD, AND COMPUTER PROGRAM

(71) Applicants: AutoNetworks Technologies, Ltd., Yokkaichi, Mie (JP); Sumitomo Wiring Systems, Ltd., Yokkaichi, Mie (JP); SUMITOMO ELECTRIC INDUSTRIES, LTD., Osaka-shi, Osaka (JP)

(72) Inventors: Katsuya Ikuta, Yokkaichi, Mie (JP); Yuuki Sugisawa, Yokkaichi, Mie (JP)

(21) Appl. No.: 15/765,398

(22) PCT Filed: Oct. 4, 2016
(86) PCT No.: PCT/JP2016/079461

§ 371 Date: Apr. 2, 2018

(30) Foreign Application Priority Data
Oct. 14, 2015 (JP) 2015-202860

(51) Int. Cl. B60R 16/02; G01R 19/00; H02J 7/14

(52) U.S. Cl. CPC B60R 16/02; H02J 7/1438; G01R 19/0092

(57) ABSTRACT

A current control device wherein a control unit instructs a drive circuit to switch on or off a FET provided in a current path is provided. Based on a detected voltage value detected by a voltage detection unit and a detected current value detected by a current sensor, the control unit estimates a resistance value in the current path after the time at which the detection is performed. The control unit calculates a resistance value by dividing a voltage value associated with the detected voltage value by a current value associated with the detected current value. Based on the estimated resistance value and a resistance value calculated using a voltage value and a current value respectively associated with a detected voltage value and a detected current value detected again after the time at which the detection was performed, the control unit determines whether or not to turn off the FET.

### CROSS-REFERENCE TO RELATED APPLICATIONS

This application is the U.S. national stage of PCT/JP2016/079461 filed Oct. 4, 2016 which claims priority of Japanese Application No. JP 2015-202860 filed Oct. 14, 2015.

### TECHNICAL FIELD

The present invention relates to a current control device and method for controlling a current flowing in a current path by switching on or off a switch provided in the current path and also to a computer program for controlling the current.

### BACKGROUND

Currently, vehicles include numerous on-board electrical devices (loads), such as a heater, a wiper, and the like, to which currents are supplied from a battery. The currents flowing from the battery to the loads are controlled by a current control device (see, for example, JP 2013-143905A).

The current control device described in JP 2013-143905A includes a switch provided in a current path of a current that flows from a battery to a load to control the current flowing from the battery to the load by switching on or off the switch.

A conventional current control device, such as the one described in JP 2013-143905A, generally has a connector connected to one end of a switch and the connector is connected to a connector connected to one end of a load. When the switch is turned on with the two connectors connected, the battery supplies a current to the load.

The potential difference between the aforementioned two connectors increases if the connection between the two connectors is cut off while the battery supplies a current to the load. Moreover, if the distance between the two connectors is short, there is a possibility of an arc discharge. If an arc discharge continues, the two connectors will be burnt out.

In order to prevent the connectors from being burnt out due to an arc discharge, it is possible to use a connector composed of a special contact material, a magnet, a capacitor, or a connector capable of detecting poor connection, or the like as the connector connected to one end of the switch or the connector connected to one end of the load. If such connectors are used, the probability of an arc discharge is reduced or the duration of an arc discharge is shortened, preventing the connectors from being burnt out.

However, connectors that can be prevented from being burnt out due to an arc discharge are usually expensive and large as they have a function other than connection.

The present invention has been made in view of these circumstances and its object is to provide a small current control device, a current control method, and a computer program that can inexpensively prevent connectors from being burnt out due to an arc discharge.

### SUMMARY

A current control device according to the present invention is a current control device for a vehicle for controlling a current flowing in a current path from a battery to a load by switching on or off a switch provided in the current path, the current control device comprising: a voltage detection unit configured to detect a voltage value in the current path; a current detection unit configured to detect a value of a current flowing in the current path; an estimation unit configured to estimate a resistance value in the current path after the time at which the current detection unit and the voltage detection unit performed the detection based on the detected voltage value detected by the voltage detection unit and the detected current value detected by the current detection unit; a resistance calculation unit configured to calculate a resistance value by dividing a voltage value associated with the detected voltage value by a current value associated with the detected current value; and a determination unit configured to determine whether or not to switch off the switch based on the resistance value estimated by the estimation unit and a resistance value calculated by the resistance calculation unit using a voltage value and a current value associated respectively with a detected voltage value and a detected current value detected again after said time.

The current control device according to the present invention may be characterized in that the estimation unit is configured to chronologically make estimates, and the estimation unit is configured to make the estimates based on the detected voltage value, the detected current value, and a resistance value estimated in the past.

The current control device according to the present invention may be characterized in that the determination unit determines to switch off the switch if the ratio calculated by dividing the resistance value calculated by the resistance calculation unit by the resistance value estimated by the estimation unit is not less than a predetermined value.

The current control device according to the present invention may be characterized in that the determination unit determines to switch off the switch if the difference calculated by subtracting the resistance value estimated by the estimation unit from the resistance value calculated by the resistance calculation unit is not less than a predetermined value.

The current control device according to the present invention is characterized by comprising: a voltage calculation unit configured to chronologically calculate voltage values associated with detected voltage values, and wherein the voltage calculation unit is configured to calculate the voltage values associated with the detected voltage values based on a voltage value calculated in the past and the detected voltage value.

The current control device according to the present invention is characterized by comprising a current calculation unit configured to chronologically calculate current values associated with detected current values, wherein the current calculation unit is configure to calculate the current values associated with the detected current values based on a current value calculated in the past and the detected current value.

A current control method according to the present invention is a current control method for controlling a current flowing in a current path from a battery to a load by switching on or off a switch provided in the current path, the method comprising: detecting a voltage value in the current path; detecting a value of a current flowing in the current path; estimating a resistance value in the current path after the time at which the detection was performed, based on the detected voltage value and the detected current value; calculate a resistance value by dividing a voltage value associated with the detected voltage value by a current value associated with the detected current value; and determining whether or not to switch off the switch based on the estimated resistance value and a resistance value calculated using a voltage value and a current value associated respectively with a detected voltage value and a detected current value detected again after said time.

A computer program according to the present invention is a characterized by causing a computer to perform processing to: estimate a resistance value in a current path from a battery to a load based on a detected voltage value detected in the current path and a detected value of a current flowing in the current path, the estimation being made after the time at which the detection was performed; calculate a resistance value by dividing a voltage value associated with the detected voltage value by a current value associated with the detected current value; and determine whether or not to switch off a switch provided in the current path based on the estimated resistance value and a resistance value calculated using a voltage value and a current value associated respectively with a detected voltage value and a detected current value detected again after said time.

In the current control device, the current control method, and the computer program according to the present invention, a voltage value in the current path from the battery to the load and a value of a current flowing in the current path are detected. A resistance value in the current path after the time at which the detection was performed, is estimated based on the detected voltage value and the detected current value. Moreover, a resistance value is calculated by dividing a voltage value associated with the detected voltage value by a current value associated with the detected current value. It is determined whether or not to turn off the switch provided in the current path on the basis of the estimated resistance value and a resistance value calculated using the voltage value and the current value respectively associated with a detected voltage value and a detected current value detected again after the time at which the detection was performed.

For example, by connecting a connector connected to one end of the switch with a connector connected to one end of the load, if the two connectors are disengaged to cause an arc discharge while a current is flowing in the current path from the battery to the load, the resistance value in the current path greatly increases. Therefore, the resistance value calculated after the two connectors are disengaged is far greater than the resistance value estimated before the disengagement. It is determined that the switch is to be switched off if the calculated resistance value is far greater than the estimated resistance value. As the switch is switched off in this way, a sustained arc discharge does not occur so that the connectors are prevented from burning out.

Furthermore, as the connector connected to one end of the switch and the connector connected to one end of the load need to have no other function than their ability of connection, the connectors can be inexpensively prevented from burning out due to an arc discharge. Moreover, according to the current control device of the present invention, as there is no need to use connectors with functions other than their ability of connection, the device is small in size.

According to the current control device of the present invention, the resistance values in the current path are estimated chronologically (over time). The resistance value in the current path is estimated based not only on the detected voltage value and the detected current value but also on a resistance value estimated in the past. This allows for accurate estimation of the resistance value.

According to the current control device of the present invention, if the ratio calculated by dividing the calculated resistance value by the estimated resistance value is not less than a predetermined value, it is determined that the switch provided in the current path is to be switched off, judging that the calculated resistance value is far greater than as the estimated resistance value.

According to the current control device of the present invention, if the difference calculated by subtracting the estimated resistance value from the calculated resistance value is not less than a predetermined value, it is determined that the switch provided in the current path is to be switched off, judging that the calculated resistance value is far greater than as the estimated resistance value.According to the current control device of the present invention, voltage values associated with the detected voltage values are calculated chronologically. The voltage value associated with the detected voltage value is calculated based not only on the detected voltage value but also on a voltage value calculated in the past. In this way, even if the detected voltage value spikes due to disturbance noise, the voltage value associated with the detected voltage value that is calculated is one on which the effect of the disturbance noise is limited.

According to the current control device of the present invention, current values associated with the detected current value are calculated chronologically. The current value associated with the detected current value is calculated based not only on the detected current value but also on a current value calculated in the past. In this way, even if the detected current value spikes due to disturbance noise, the current value associated with the detected current value that is calculated is one on which the effect of the disturbance noise is limited.

According to the current control device of the present invention, connectors can be inexpensively prevented from being burnt out due to an arc discharge and the device is small in size.

According to the current control method and the computer program of the present invention, connectors can be inexpensively prevented from being burnt out due to an arc discharge.

### BRIEF DESCRIPTION OF DRAWINGS

FIG. 1 is a block diagram illustrating the configuration of the main part of a power supply system according to this embodiment.

FIG. 2 is a flowchart illustrating the sequence of initial value setting processing carried out by a control unit.

FIG. 3 is a flowchart illustrating the sequence of a load-side burnout prevention processing carried out by the control unit.

FIG. 4 is a flowchart illustrating the sequence of the load-side burnout prevention processing carried out by the control unit.

FIG. 5 is a diagram illustrating the operation of a current control device.

### DETAILED DESCRIPTION OF PREFERRED EMBODIMENTS

The present invention will be described in detail hereinafter with reference to the drawings that illustrate embodiments thereof.

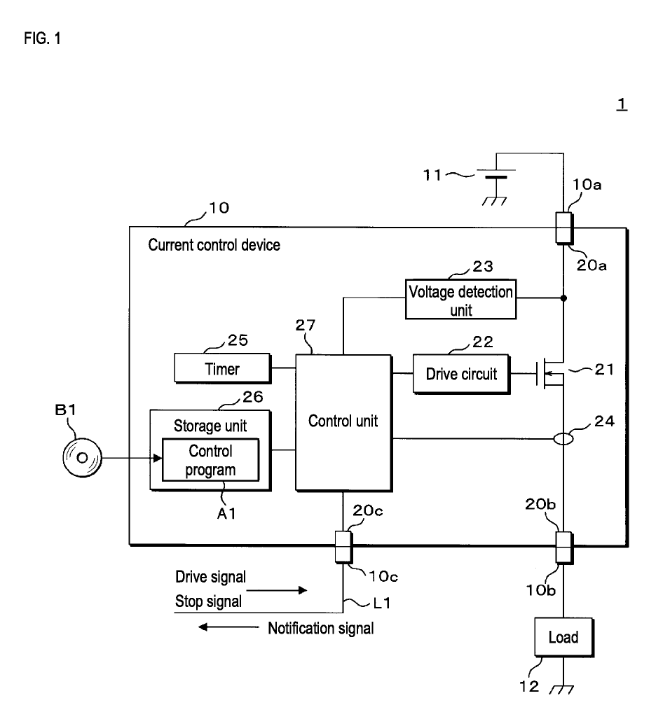

FIG. 1 is a block diagram illustrating the configuration of the main part of a power supply system 1 according to this embodiment. The power supply system 1 is suitably installed onboard a vehicle and includes a current control device 10, a battery 11, and a load 12. The current control device 10 includes connectors 20a, 20b, and 20c. The power supply system 1 also includes connectors 10a, 10b, and 10c detachably connected to the connectors 20a, 20b, and 20c, of the current control device 10 respectively.

The connector 10a is connected to the positive electrode of the battery 11. The connector 10b is connected to one end of the load 12. The negative electrode of the battery 11 and the other end of the load 12 are grounded. A communication line L1 is connected to the connector 10c.

When the connectors 10a, 10b, and 10c are connected to the connectors 20a, 20b, and 20c, respectively, the current control device 10 controls the current flowing from the battery 11 to the load 12.

Specifically, the current control device 10 receives, via the communication line L1, a drive signal that instructs the current control device 10 to drive the load 12 and a stop signal that instructs the current control device 10 to stop the driving of the load 12. Upon receiving the drive signal, the current control device 10 causes the battery 11 to supply a current to the load 12 to drive the load 12. Upon receiving the stop signal, the current control device 10 cuts off the current flowing from the battery 11 to the load 12 to stop the driving of the load 12.

The current control device 10 detects whether or not the connection between the connectors 10a and 20a has been cut off while the load 12 is driven, in order to prevent a sustained arc discharge between the connectors 10a and 20a. If it is determined that the connection between the connectors 10a and 20a has been cut off, the current control device 10 shuts off the current flowing from the battery 11 to the load 12.

Similarly, the current control device 10 detects whether or not the connection between the connectors 10b and 20b has been cut off while the load 12 is driven, in order to prevent a sustained arc discharge between the connectors 10b and 20b. If it is determined that the connection between the connectors 10b and 20b has been cut off, the current control device 10 shuts off the current flowing from the battery 11 to the load 12.

If the current control device 10 shuts off the current flowing from the battery 11 to the load 12 while driving the load 12, the current control device outputs, via the communication line L1, an announcement signal that announces that the connection between the connectors 10a and 20a or between the connectors 10b and 20b has been cut off. This turns on an unshown lamp or displays an unshown message or the like, notifying the user that the connection between the connectors 10a and 20a or between the connectors 10b and 20b has been cut off.

The load 12 is, for example, a PTC (Positive Temperature Coefficient) heater with a resistance component. The resistance value of the load 12 changes, for example, depending on the temperature of the load 12.

In addition to the connectors 20a, 20b, and 20c, the current control device 10 includes an N-channel FET (Field Effective Transistor) 21, a drive circuit 22, a voltage detection unit 23, a current sensor 24, a timer 25, a storage unit 26, and a control unit 27. The drain of the FET 21 is connected to the connector 20a and the source of the FET 21 is connected to the connector 20b. The gate of the FET 21 is connected to the drive circuit 22. The drive circuit 22 is also connected to the control unit 27. Furthermore, the control unit 27 is connected to each of the connector 20c, the voltage detection unit 23, the current sensor 24, the timer 25, and the storage unit 26. The voltage detection unit 23 is also connected to the drain of the FET 21 as well as to the control unit 27.

The FET 21 functions as a switch. The drive circuit 22 outputs a high-level voltage or a low-level voltage to the gate of the FET 21. The voltage value of the high-level voltage is higher than the voltage value of the low-level voltage. When the high-level voltage is outputted to the gate of the FET 21, a current can flow between the drain and the source of the FET 21 to keep the FET 21 on. When the low-level voltage is outputted to the gate of the FET 21, no current flows between the drain and the source of the FET 21, thus keeping the FET 21 off.

When the FET 21 is switched on, a current flows from the battery 11 to the load 12 via the connector 20a, the FET 21, and the connector 20b. In this way, the current control device 10 has a current path provided from the battery 11 and the load 12 with the FET 21 provided in the current path. When a current flows in the current path, the current is supplied to the load 12 to drive the load 12.

When the FET 21 is switched off, the current flowing in the current path is shut off to stop the operation of the load 12.

The drive circuit 22 switches on the FET 21 to drive the load 12 by outputting a high-level voltage to the gate of the FET 21. In addition, the drive circuit 22 switches off the FET 21 to stop the driving of the load 12 by outputting a low-level voltage to the gate of the FET 21. The drive circuit 22 outputs the high-level voltage or the low-level voltage to the gate of the FET 21 in accordance with an instruction from the control unit 27 to drive the load 12 or stop the driving of the load 12. The control unit 27 controls the current flowing in the current path by causing the drive circuit 22 to switch on or off the FET 21.

The voltage detection unit 23 detects the voltage value in the current path, in particular, the voltage value at the drain of the FET 21. The voltage detection unit 23 outputs to the control unit 27 voltage information that indicates the detected voltage value that it has detected. The control unit 27 obtains the voltage information from the voltage detection unit 23. The detected voltage value indicated by the voltage information obtained by the control unit 27 is approximately the same as the detected voltage value detected by the voltage detection unit 23 when the control unit 27 obtains that voltage information.

The current sensor 24 functions as a current detection unit to detect the value of the current flowing in the current path. The current sensor 24 outputs to the control unit 27 current information indicating the detected current value that it has detected. The control unit 27 obtains the current information from the current sensor 24. The detected current value indicated by the current information obtained by the control unit 27 is approximately the same as the detected current value detected by the current detection unit 24 when the control unit 27 obtains that current information.

The timer 25 starts clocking the time according to the instruction of the control unit 27. The time clocked by the timer 25 is read from the timer 25 by the control unit 27. The timer 25 terminates clocking according to the instruction of the control unit 27.

The storage unit 26 is a non-volatile memory. The storage unit 26 stores a control program A1.

The control unit 27 includes an unshown CPU (Central Processing Unit) and carries out drive control processing, battery-side burnout prevention processing, and load-side burnout prevention processing by executing the control program A1 stored in the storage unit 26. The drive control processing controls the driving of the load 12. The battery-side burnout prevention processing prevents the connectors 10a and 20a from being burnt out due to a sustained arc discharge between the connectors 10a and 20a. The load-side burnout prevention processing prevents the connectors 10b and 20b from being burnt out due to a sustained arc discharge between the connectors 10b and 20b.

It should be noted that the control program A1 may also be stored on a storage medium B1 that is readable by a computer. In this case, the control program A1 is read from the storage medium B1 by an unshown read-out device and stored in the storage unit 26. The storage medium B1 is an optical disk, a flexible disk, a magnetic disk, a magneto-optical disk, a semiconductor memory, or the like. The optical disk is a CD (Compact Disk)-ROM (Read Only Memory), DVD (Digital Versatile Disc)-ROM, BD (Blue-ray® Disc), or the like. The magnetic disk is a hard disk, for example. Alternatively, the control program A1 may be downloaded from an unshown external device connected to an unshown communication network so that the downloaded control program A1 may be stored on the storage unit 26.

The control unit 27 periodically carries out the drive control processing. First, the control unit 27 determines whether or not a drive signal has been inputted into the control unit 27 via the connector 10c and 20c. If it is determined that a drive signal has been inputted, the control unit 27 instructs the drive circuit 22 to switch on the FET 21. This permits a current to flow in the current path to supply the current to the load 12 from the battery 11. The load 12 is operated by the current supplied to the load 12. The control unit 27 terminates the drive control processing after switching on the FET 21.

If it is determined that no drive signal has been inputted, the control unit 27 determines whether or not a stop signal has been inputted into the control unit 27 via the connector 10c and 20c. If it is determined that a stop signal has been inputted, the control unit 27 instructs the drive circuit 22 to switch off the FET 21. Thus, no current flows in the current path any longer, so that no current is supplied to the load 12 from the battery 11. The operation of the load 12 is halted due to the stoppage of the supply of current to the load 12. If it is determined that no stop signal has been inputted or after instructing the drive circuit 22 to switch off the FET 21, the control unit 27 terminates the drive control processing.

When the FET 21 is on, the control unit 27 periodically carries out battery-side burnout prevention processing. When the connectors 10a and 20a are connected normally, the detected voltage value detected by the voltage detection unit 23 is approximately the same as the output voltage value of the battery 11 and is not less than a threshold voltage value. If the connection between the connectors 10a and 20a is cut off and causes an arc discharge, a large voltage drop occurs across the connectors 10a and 20a. If no arc discharge is occurring with the connection between the connectors 10a and 20a cut off, the detected voltage value detected by the voltage detection unit 23 is zero volt. If the connection between the connectors 10a and 20a is cut off, the detected voltage value detected by the voltage detection unit 23 becomes less than the threshold voltage value regardless of whether or not an arc discharge is occurring. The threshold voltage value is fixed and stored in the storage unit 26 in advance.

In battery-side burnout prevention processing, the control unit 27 obtains voltage information from the voltage detection unit 23 and determines whether or not the voltage value indicated by the obtained voltage information is less than the threshold voltage. If it determines that the voltage value is not less than the threshold voltage value, then the control unit 27 terminates the battery-side burnout prevention processing with the FET 21 switched on. If it determines that the voltage value is less than the threshold voltage value, the control unit 27 instructs the drive circuit 22 to switch off the FET 21 and terminates the battery-side burnout prevention processing. In the battery-side burnout prevention processing, if the connection between the connectors 10a and 20a is cut off, causing an arc discharge, the FET 21 is switched off, so that sustained arc discharge does not occur, to prevent the connectors 10a and 20a from burning out.

Also in the battery-side burnout prevention processing, if the control unit 27 instructs the drive circuit 22 to switch off the FET 21, the control unit outputs, via the communication line L1, an announcement signal that announces that the connection between the connectors 10a and 20a has been cut off. This notifies the user that the connection between the connectors 10a and 20a has been cut off.

The control unit 27 periodically carries out load-side burnout prevention processing using voltage values V0 and V1, current values I0 and I1, resistance values R1 and R2, and variable values K1, P1, and P2. These values are updated successively. An initial variable value P1 and an initial resistance value R1 are stored in the storage unit 26 in advance. These initial values are used in the first load-side burnout prevention processing carried out after the FET 21 has been switched on from off. Furthermore, before carrying out the first load-side burnout prevention processing carried out after the FET 21 has been switched on from off, the control unit 27 executes the control program A1 to perform initial value setting processing to set the initial values of the voltage value V0 and the current value I0.

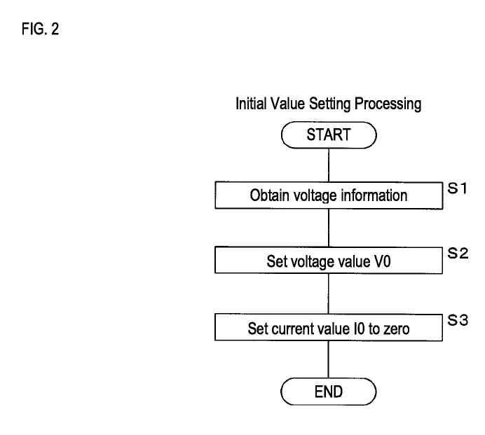

FIG. 2 is a flowchart illustrating the sequence of the initial value setting processing carried out by the control unit 27. First, the control unit 27 obtains from the voltage detection unit 23 voltage information that indicates the detected voltage value detected by the voltage detection unit 23 itself (Step S1). Next, the control unit 27 sets the voltage value V0 as the detected voltage value indicated by the voltage information obtained in Step S1 (Step S2) and sets the current value I0 to zero (Step S3). After carrying out Step S3, the control unit 27 terminates the initial value setting processing. Subsequently, the control unit 27 carries out initial value setting processing if the FET 21 is switched back on from off again.

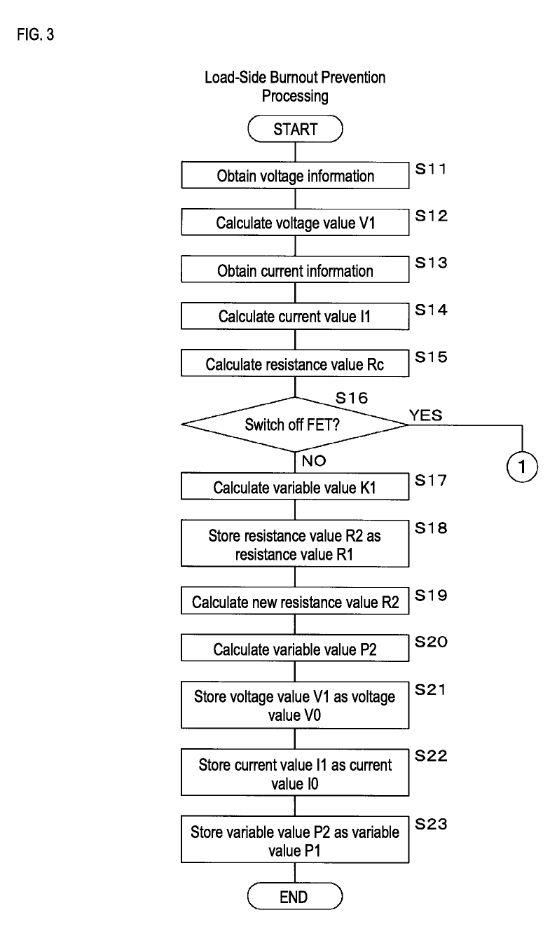

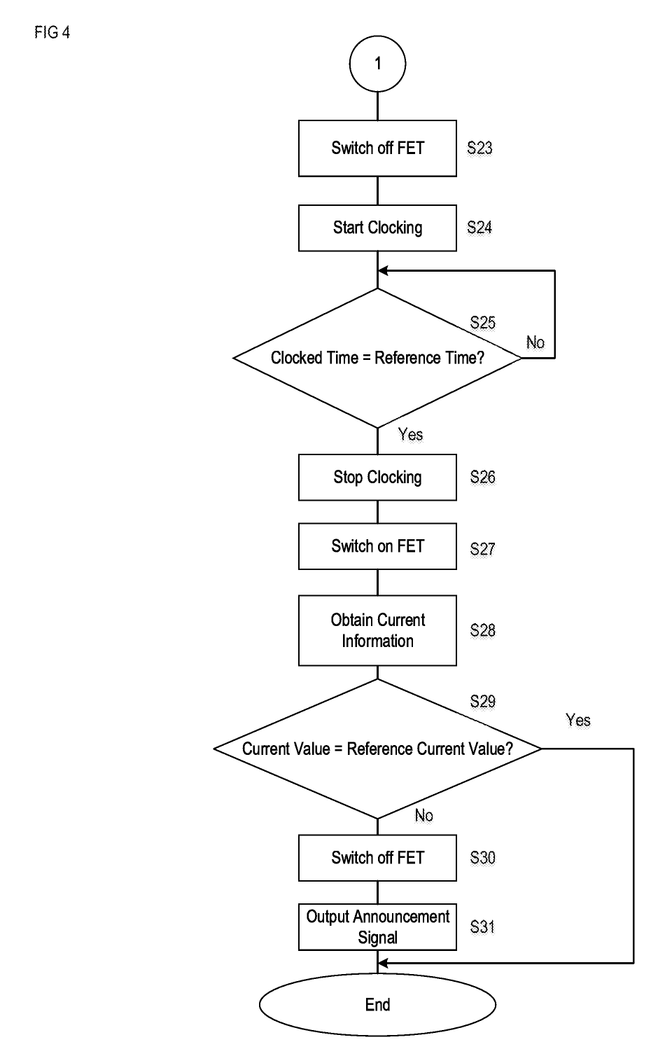

FIGS. 3 and 4 are flowcharts illustrating the sequence of the load-side burnout prevention processing carried out by the control unit 27. When the FET 21 is on, the control unit 27 periodically carries out load-side burnout prevention processing after performing initial value setting processing. In the load-side burnout prevention processing, the control unit 27 first obtains voltage information from the voltage detection unit 23 (Step S11).

The control unit 27 calculates a voltage value V1 by substituting into the Equation (1) below the detected voltage value Vd indicated by the voltage information obtained in Step S11 and the voltage value V0 stored in the storage unit 26 (Step S12).

V1=(1−α)×V0+α×Vd (1)

where α is a constant greater than 0 and less than 1.

As indicated by the Equation (1), the voltage value V1 is a voltage value associated with the detected voltage value Vd. As discussed above, as the control unit 27 periodically performs load-side burnout prevention processing, the control unit 27 chronologically calculates the voltage value V1. In the first load-side burnout prevention processing performed after the FET 21 has been switched from off to on, the voltage value V0 is the initial value set in the initial value setting processing. In the second and subsequent load-side burnout prevention processing, as noted above, the voltage value V0 is the voltage value V1 calculated in Step S12 of the last load-side burnout prevention processing. In Step S12, the control unit 27 calculates the voltage value V1 based on the voltage value V0, which is the voltage value V1 calculated in the past in Step S12 and the detected voltage value Vd.

In this way, even if the detected voltage value Vd spikes due to disturbance noise, Step S12 calculates a voltage value V1 on which the effect of the disturbance noise is limited. In other words, as the control unit 27 performs Step S12, the high frequency noise superimposed on the detected voltage value Vd is eliminated, providing an effect equivalent to that of a low pass filter. The control unit 27 functions as a voltage calculation unit.

It should be noted that the past voltage value used in Step S12 is not limited to the voltage value V1 calculated in Step S12 of the last load-side burnout prevention processing; for example, it may also be the voltage value V1 calculated in Step S12 of the second last load-side burnout prevention processing. Moreover, the number of past voltage values used in Step S12 is not limited to one, but it may be two or more. For example, the two voltage values V1 calculated in Step S12 of the last and second last load-side burnout prevention processing may be used as the past voltage values in Step S12.

After performing Step S12, the control unit 27 obtains current information from the current sensor 24 (Step S13) and calculates a current value I1 by substituting into the Equation (2) below the detected current value Id indicated by the obtained current information and the current value I0 stored in the storage unit 26 (Step S14).

I1=(1−β)×I0+β×Id (2)

where β is a constant greater than 0 and less than 1.

As indicated by Equation (2), the current value I1 is a voltage value associated with the detected current value Id. As discussed above, as the control unit 27 periodically performs load-side burnout prevention processing, the control unit 27 calculates the current value I1 chronologically (over time). In the first load-side burnout prevention processing performed after the FET 21 has been switched from off to on, the current value I0 is the initial value set in the initial value setting processing, in other words, zero. In the second and subsequent load-side burnout prevention processing, as noted above, the current value I0 is the current value I1 calculated in Step S14 of the last load-side burnout prevention processing. In Step S14, the control unit 27 calculates the current value I1 based on the current value I0, which is the current value I1 calculated in the past in Step S14 and the detected current value Id.

In this way, even if the detected current value Id spikes due to disturbance noise, Step S14 calculates a current value I1 on which the effect of the disturbance noise is limited. In other words, as the control unit 27 performs Step S14, the high frequency noise superimposed on the detected current value Id is eliminated, providing an effect equivalent to that of a low pass filter. The control unit 27 functions as a current calculation unit.

It should be noted that the past current value used in Step S14 is not limited to the current value I1 calculated in Step S14 of the last load-side burnout prevention processing; for example, it may also be the current value I1 calculated in Step S14 of the second last load-side burnout prevention processing. Moreover, the number of past current values used in Step S14 is not limited to one, but it may be two or more. For example, the two current values I1 calculated in Step S14 of the last and second last load-side burnout prevention processing may be used as the past current values in Step S14.

Next, the control unit 27 calculates a resistance value Rc by dividing the voltage value V1 calculated in Step S12 by the current value I1 calculated in Step S14 (Step S15). The control unit 27 functions as a resistance calculation unit.

The control unit 27 then determines whether or not to switch off the FET 21 based on the resistance value R2 stored in the storage unit 26 and the resistance value Rc calculated in Step S15 (Step S16). In this case, the resistance value R2 was calculated in the last load-side burnout prevention processing and is an estimate of the resistance value Rc calculated in Step S15 of the current load-side burnout prevention processing. Needless to say, the resistance value Rc is calculated using the voltage value V1 and the current value I1 associated respectively with a detected voltage value Vd and a detected current value Id detected again after the time at which the voltage detection unit 23 and the current sensor 24 carried out detection to calculate the resistance value R2 in the last load-side burnout prevention processing.

In Step S16, if there is a high probability that the connection of the connectors 10b and 20b is cut off, the control unit 27 determines to switch off the FET 21 to prevent repeated occurrences of a sustained arc discharge between the connectors 10b and 20b. If there is a low probability that the connection between the connectors 10b and 20b is cut off, the control device 27 determines not to switch off the FET 21.

If the connection between the connectors 10b and 20b is cut off, the resistance value between the connectors 10b and 20b greatly increases regardless of whether or not an arc discharge is occurring. This greatly reduces the value of the current flowing in the current path as well as the current value I1 calculated in Step S14. As a result, the resistance value Rc greatly increases. The resistance value R2 is an estimate on the assumption that the connectors 10b and 20b are connected. Therefore, if the connection between the connectors 10b and 20b has been cut off after the resistance value R2 was calculated in the last load-side burnout prevention processing and before the start of the current load-side burnout prevention processing, the resistance value Rc calculated in Step S15 is far greater than the resistance value R2 stored in the storage unit 26.

Accordingly, if the resistance value Rc calculated in Step S15 is far greater than the resistance value R2 stored in the storage unit 26, there is a high probability that the connection between the connectors 10b and 20b is cut off. Accordingly, if the resistance value Rc calculated in Step S15 is approximately the same as the resistance value R2 stored in the storage unit 26, there is a low probability that the connection between the connectors 10b and 20b is cut off.

In Step S16, if the resistance value Rc is far greater than the resistance value R2, it is determined that the FET 21 is to be switched off, and if the resistance value Rc is approximately the same as the resistance value R2, it is determined that the FET 21 is not to be switched off.

The following are two possible schemes for the control unit 27 to determine in Step S16 whether or not to switch off the FET 21.

In the first scheme, if the ratio calculated by dividing the resistance value Rc calculated in Step S15 by the resistance value R2 stored in the storage unit 26 is not less than a reference value, the control unit 27 determines to switch off the FET 21, judging that the resistance value Rc is far greater than the resistance value R2. Additionally, if the ratio calculated by dividing the resistance value Rc by the resistance value R2 is less than a reference value, the control unit 27 determines not to switch off the FET 21, judging that the resistance value Rc is approximately the same as the resistance value R2. In the first scheme, the reference value is greater than 1.

In the second scheme, if the difference calculated by subtracting the resistance value R2 stored in the storage unit 26 from the resistance value Rc calculated in Step S15 is not less than a reference value, the control unit 27 determines to switch off the FET 21, judging that the resistance value Rc is far greater than the resistance value R2. Additionally, if the difference calculated by subtracting the resistance value R2 from the resistance value Rc is less than a reference value, the control unit 27 determines not to switch off the FET 21, judging that the resistance value Rc is approximately the same as the resistance value R2.

The scheme in Step S16 may be either the first scheme or the second scheme. Regardless of whether the scheme in Step S16 is the first scheme or the second scheme, the reference value is fixed and stored in the storage unit 26 in advance. The control unit 27 functions as a determination unit.

The voltage detection unit 27, if it is determined not to switch off the FET 21 (NO in Step S16), calculates a variable value K1 by substituting the current value I1 calculated in Step S14 and the variable value P1 stored in the storage unit 26 into the Equation (3) below (Step S17).

K1=I1×P1/(I1²×P1+E) (3)

where E is a constant.

The variable value P1 is the variable value P2 calculated in the last load-side burnout prevention processing. The initial variable value P1 stored in the storage unit 26 is used in Step S17 of the first load-side burnout prevention processing carried out by the control unit 27 after the FET 21 has been switched from off to on.

It should be noted that in the first load-side burnout prevention processing performed after the FET 21 has been switched from off to on, the control unit 27 carries out Step S17 after Step S14 without carrying out Steps S15 and S16. This is because, in the first load-side burnout prevention processing, there is no resistance value R2 to be used in Step S16.

The control unit 27, after carrying out Step S17, stores the resistance value R2 stored in the storage unit 26 as the resistance value R1 (Step S18). This updates the resistance value R1 stored in the storage unit 26.

Next, the control unit 27 calculates a new resistance value R2 by substituting into the Equation (4) below the voltage value V1 calculated in Step S12, the current value I1 calculated in Step S14, K1 calculated in Step S17, and the resistance value R1 stored in the storage unit 26 (Step S19).

R2=R1+K1×(V1−I1×R1) (4)

The resistance value R2 calculated in Step S19 is an estimate of the resistance value Rc to be calculated in Step S15 of the next load-side burnout prevention processing. In other words, the resistance value R2 calculated in Step S19 is an estimate of the value of resistance of the current path after the time at which the voltage detection unit 23 and the current sensor 24 carried out detection in the current load-side burnout prevention processing.

As discussed above, as the control unit 27 periodically performs load-side burnout prevention processing, the control unit 27 chronologicaly estimates the resistance value R2. The voltage value V1 is calculated by substituting the detected voltage value Vd into the Equation (1). The current value I1 is calculated by substituting the detected current value Id into the Equation (2). The resistance value R1 is the resistance value R2 calculated in Step S19 of the last load-side burnout prevention processing.

Accordingly, in Step S19, the control unit 27 estimate a new resistance value R2 based on the detected voltage value Vd, the detected current value Id, the resistance value R1, which is the resistance value R2 estimated in the past. The control unit 27 functions as an estimation unit. As a new resistance value R2 is estimated based not only on the detected voltage value Vd and the detected current value Id but also on the resistance value R2 estimated in the past, the newly estimated resistance value R2 is accurate.

The resistance value R2 stored in the storage unit 26 is rewritten by the new resistance value R2 calculated by the control unit 27 in Step S19. The new resistance value R2 will be used in Step S16 of the next load-side burnout prevention processing.

It should be noted that in the first load-side burnout prevention processing performed by the control unit 27 after the FET 21 has been switched from off to on, the control unit 27 carries out Step S19 after Step S17 without carrying out Step S18. This is because, in the first load-side burnout prevention processing, there is no resistance value R2 to be stored in Step S18. The initial resistance value R1 stored in the storage unit 26 is used in Step S19 of the first load-side burnout prevention processing carried out by the control unit 27 after the FET 21 has been switched from off to on.

After carrying out Step S19, the control unit 27 calculates the variable value P2 by substituting into the Equation (5) below the current value I1 calculated in Step S14, the variable value K1 calculated in Step S17, and the variable value P1 stored in the storage unit 26 (Step S20).

P2=(1−K1×I1)×P1 (5)

Equations (3), (4), and (5) are derived from the Kalman filter equation.

Next, the control unit 27 stores in the storage unit 26 the voltage value V1 calculated in Step S12 as the voltage value V0 (Step S21), stores in the storage unit 26 the current value I1 calculated in Step S14 as the current value I0 (Step S22), and stores in the storage unit 26 the variable value P2 calculated in Step S20 as the variable value P1 (Step S23). The control unit 27 updates the voltage value V0, the current value I0, and the variable value P1 stored in the storage unit 26 by carrying out Steps S21, S22, and S23. The updated voltage value V0, current value I0, and variable value P1 will be used in the next load-side burnout prevention processing.

After carrying out Step S23, the control unit 27 terminates the current load-side burnout prevention processing.

If it is determined to switch off the FET 21 (YES in Step S16), the control unit 27 instructs the drive circuit 22 to switch the FET 21 from on to off (Step S23). As this interrupts the current flowing in the current path, no voltage drop occurs between the connectors 10b and 20b. If no voltage drop occurs between the connectors 10b and 20b, no arc discharge occurs between the connectors 10b and 20b.

Accordingly, if an arc discharge between the connectors 10b and 20b is occurring because the connection between the connectors 10b and 20b has been cut off, the arc discharge stops when the control unit 27 performs Step S23. In this way, a sustained arc discharge does not occur so as to prevent the connectors 10b and 20b from burning out. Furthermore, as each of the connectors 10b and 20b needs to have no other function than its ability of connection, the connectors 10b and 20b can be inexpensively prevented from burning out due to an arc discharge and the current control device 10 is small in size.

In the process from Step S24 and later, the control unit 27 determines that the control unit has not erroneously caused the drive circuit 22 to switch off the FET 21.

After carrying out Step S23, the control unit 27 instructs the timer 25 to start clocking (Step S24) and determines whether or not the time clocked by the timer 25 is not less than reference time (Step S25). The reference time is fixed and stored in the storage unit 26 in advance. If the clocked time is less than the reference time (NO in Step S25), the control unit 27 performs Step S25 again and stands by until the clocked time becomes not less than the reference time.

If it is determined that the clocked time is not less than the reference time (YES in Step S25), the control unit 27 instructs the timer 25 to stop the clocking (Step S26) and instructs the drive circuit 22 to switch on the FET 21 (Step S27). After carrying out Step S27, as in Step S13, the control unit 27 obtains current information from the current sensor 24 (Step S28) and determines whether or not the current value indicated by the obtained current information is not less than the reference current value (Step S29).

The reference current value is fixed and stored in the storage unit 26 in advance. If the connectors 10a and 20a are connected normally and the connectors 10b and 20b are connected normally, the reference current value is smaller than the value of the current flowing in the current path when the FET 21 is on. If the connection between then connectors 10b and 20b has been cut off, the reference current value is greater than the value of the current flowing in the current path when the FET 21 is on.

Accordingly, if the current value indicated by the current information obtained in Step S28 is not less than the reference current value, this indicates that the FET 21 was erroneously switched off in Step S23. Also, if the current value indicated by the current information obtained in Step S28 is less than the reference current value, this indicates that the FET 21 was correctly switched off in Step S23.

If it is determined that the current value is not less than the reference current value (YES in Step S29), the control unit 27 terminates the load-side burnout prevention processing with the FET 21 switched on.

If it is determined that the current value is less than the reference current value (NO in Step S29), the control unit 27 instructs the drive circuit 22 to switch off the FET 21 again (Step S30), and outputs, via the communication line L1, an announcement signal that announces that the connection between the connectors 10b and 20b has been cut off. This notifies the user that the connection between the connectors 10b and 20b has been cut off. After carrying out Step S31, the control unit 27 terminates the load-side burnout prevention processing.

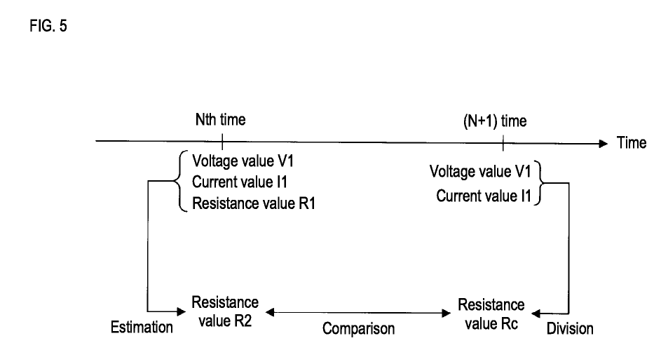

FIG. 5 is a diagram illustrating the operation of the current control device 10. In the Nth (N=an integer greater than 1) load-side burnout prevention processing performed after the FET 21 is switched from off to on, the current control device 10 estimates the resistance value R2, which is the resistance value Rc calculated in the (N+1)th load-side burnout prevention processing. At this point, the control unit 27 make an estimate based on a voltage value V1 associated with a detected voltage value Vd, a current value Id associated with a detected current value Id, and a resistance value R1, which is a resistance value R2 of the current path calculated in the (N−1)th load-side burnout prevention processing.

In the (N+1)th load-side burnout prevention processing, the control unit 27 calculates the resistance value Rc by dividing the voltage value V1 by the current value I1. Then, if the resistance value R2 estimated in the Nth load-side burnout prevention processing is far greater than the resistance value Rc calculated in the (N+1)th load-side burnout prevention processing, the control unit 27 determines that the connectors 10b and 20b have been disconnected. Whether or not the resistance value R2 is far greater than the resistance value Rc is determined, as described above, using the ratio calculated by dividing the resistance value R2 by the resistance value Rc or the difference calculated by subtracting the resistance value Rc from the resistance value R2.

If the resistance value of the load 12 changes depending on the temperature of the load 12, the longer a current is supplied to the load 12, the higher the temperature of the load 12 rises, causing the resistance value of the load 12 to change with the passage of time.

As described above, the current control device 10 compares the resistance value R2 estimated in the Nth time with the resistance value Rc calculated in the (N+1)th time. Accordingly, even if the resistance value of the load 12 changes with the passage of time as described above, since the resistance value R2 follows the change in the resistance value of the load 12, there is a low probability that the FET 21 is erroneously switched off when the connectors 10b and 20b are connected normally.

It should be noted that the voltage value V1 associated with the detected voltage value Vd may be the detected voltage value Vd itself. Likewise, the current value I1 associated with the detected current value Id may be the detected current value Id itself. In either case, a sustained arc discharge does not occur so that the connectors 10b and 20b are prevented from burning out.

Moreover, the FET 21 is not limited to an N-channel FET but it may also be a P-channel FET as what is required is its ability to function as a switch. Furthermore, an IGBT (Insulated Gate Bipolar Transistor), a bipolar transistor, or the like may be used instead of the FET 21.

The disclosed embodiments should be considered in all respects only to be illustrative and not restrictive. The scope of the present invention is indicated by the claims rather than the above described sense, and all changes that come within the meaning and range of equivalency of the claims are to be encompassed within the scope of the invention.

1. A current control device for a vehicle for controlling a current flowing in a current path from a battery to a load by switching on or off a switch provided in the current path, the current control device comprising:
a voltage detection unit configured to detect a voltage value in the current path;
a current detection unit configured to detect a value of a current flowing in the current path;
an estimation unit configured to estimate a resistance value in the current path after the time at which the current detection unit and the voltage detection unit have performed the detection based on the detected voltage value detected by the voltage detection unit and the detected current value detected by the current detection unit;
a resistance calculation unit configured to calculate a resistance value by dividing a voltage value associated with the detected voltage value by a current value associated with the detected current value; and
a determination unit configured to determine whether or not to switch off the switch based on the resistance value estimated by the estimation unit and a resistance value calculated by the resistance calculation unit using a voltage value and a current value associated respectively with a detected voltage value and a detected current value detected again after said time.

2. The current control device according to claim 1, wherein the estimation unit is configured to chronologically make estimates, and
the estimation unit is configured to make the estimates based on the detected voltage value, the detected current value, and a resistance value estimated in the past.

3. The current control device according to claim 1, wherein the determination unit is configured to determine to switch off the switch if the ratio calculated by dividing the resistance value calculated by the resistance calculation unit by the resistance value estimated by the estimation unit is not less than a predetermined value.

4. The current control device according to claim 1, wherein the determination unit is configured to determine to switch off the switch if the difference calculated by subtracting the resistance value estimated by the estimation unit from the resistance value calculated by the resistance calculation unit is not less than a predetermined value.

5. The current control device according to claim 1, characterized by comprising a voltage calculation unit configured to chronologically calculate voltage values associated with detected voltage values,
wherein the voltage calculation unit is configured to calculate the voltage values associated with the detected voltage values based on a voltage value calculated in the past and the detected voltage value.

6. The current control device according to claim 1, characterized by comprising a current calculation unit configured to chronologically calculate current values associated with detected current values,
wherein the current calculation unit calculates the current values associated with the detected current values based on a current value calculated in the past and the detected current value.

7. A current control method for controlling a current flowing in a current path from a battery to a load by switching on or off a switch provided in the current path, the method comprising:
detecting a voltage value in the current path;
detecting a value of a current flowing in the current path;
estimating a resistance value in the current path after the time at which the detection was performed, based on the detected voltage value and the detected current value;
calculating a resistance value by dividing a voltage value associated with the detected voltage value by a current value associated with the detected current value; and
determining whether or not to switch off the switch based on the estimated resistance value and a resistance value calculated using a voltage value and a current value associated respectively with a detected voltage value and a detected current value detected again after said time.

8. A computer program characterized by causing a computer to perform processing to:
estimate a resistance value in a current path from a battery to a load based on a detected voltage value detected in the current path and a detected value of a current flowing in the current path, the estimation being made after the time at which the detection was performed;
calculate a resistance value by dividing a voltage value associated with the detected voltage value by a current value associated with the detected current value; and
determine whether or not to switch off a switch provided in the current path based on the estimated resistance value and a resistance value calculated using a voltage value and a current value associated respectively with a detected voltage value and a detected current value detected again after said time.

9. The current control device according to claim 2, wherein the determination unit is configured to determine to switch off the switch if the ratio calculated by dividing the resistance value calculated by the resistance calculation unit by the resistance value estimated by the estimation unit is not less than a predetermined value.

10. The current control device according to claim 2, wherein the determination unit is configured to determine to switch off the switch if the difference calculated by subtracting the resistance value estimated by the estimation unit from the resistance value calculated by the resistance calculation unit is not less than a predetermined value.

11. The current control device according to claim 2, characterized by comprising a voltage calculation unit configured to chronologically calculate voltage values associated with detected voltage values,
wherein the voltage calculation unit is configured to calculate the voltage values associated with the detected voltage values based on a voltage value calculated in the past and the detected voltage value.

12. The current control device according to claim 3, characterized by comprising a voltage calculation unit configured to chronologically calculate voltage values associated with detected voltage values,
wherein the voltage calculation unit is configured to calculate the voltage values associated with the detected voltage values based on a voltage value calculated in the past and the detected voltage value.

13. The current control device according to claim 4, characterized by comprising a voltage calculation unit configured to chronologically calculate voltage values associated with detected voltage values,
wherein the voltage calculation unit is configured to calculate the voltage values associated with the detected voltage values based on a voltage value calculated in the past and the detected voltage value.

14. The current control device according to claim 2, characterized by comprising a current calculation unit configured to chronologically calculate current values associated with detected current values,
wherein the current calculation unit calculates the current values associated with the detected current values based on a current value calculated in the past and the detected current value.

15. The current control device according to claim 3, characterized by comprising a current calculation unit configured to chronologically calculate current values associated with detected current values,
wherein the current calculation unit calculates the current values associated with the detected current values based on a current value calculated in the past and the detected current value.

16. The current control device according to claim 4, characterized by comprising a current calculation unit configured to chronologically calculate current values associated with detected current values,
wherein the current calculation unit calculates the current values associated with the detected current values based on a current value calculated in the past and the detected current value.

17. The current control device according to claim 5, characterized by comprising a current calculation unit configured to chronologically calculate current values associated with detected current values,
wherein the current calculation unit calculates the current values associated with the detected current values based on a current value calculated in the past and the detected current value.
